(19) United States
(12) Patent Application Publication
(10) Pub. No.: US 2026/0068638 A1
(43) Pub. Date: Mar. 5, 2026

(54) SEMICONDUCTOR INTEGRATED CIRCUIT DEVICE

(71) Applicant: Socionext Inc., Yokohama-shi (JP)

(72) Inventor: Hisatsugu TAKASHIMA, Yokohama-shi (JP)

(21) Appl. No.: 19/380,241

(22) Filed: Nov. 5, 2025

Related U.S. Application Data
(63) Continuation of application No. PCT/JP2023/033896, filed on Sep. 19, 2023.

(51) Int. Cl. H01L 23/528; H03F 3/45; H10D 30/00; H10D 30/43; H10D 62/10; H10D 84/85

(52) U.S. Cl. CPC H01L 23/528; H03F 3/4521; H10D 30/43; H10D 30/502; H10D 62/121; H10D 84/851

(57) ABSTRACT

A semiconductor integrated circuit device includes transistors that perform differential amplification. Dummy transistors are formed at positions different from the transistors in the depth direction and overlapping the transistors in planar view. Active regions of the transistors are formed line-symmetrically, and active regions of the dummy transistors are also formed line-symmetrically with respect to the same symmetric axis. In the active regions of the dummy transistors, sources and drains at symmetrical positions have the same electrical connection state.

### CROSS-REFERENCE TO RELATED APPLICATIONS

This is a continuation of International Application No. PCT/JP2023/033896 filed on Sep. 19, 2023. The entire disclosure of this application is incorporated by reference herein.

### BACKGROUND

The present disclosure relates to a layout structure of a semiconductor integrated circuit device.

For higher integration of a semiconductor integrated circuit device, there is available a complementary field effect transistor (CFET) technique in which transistors are stacked one upon another in the direction normal to the substrate. The direction normal to the substrate is herein called the depth direction. Moreover, for higher integration of a semiconductor integrated circuit device, there is proposed a technique in which interconnects are provided right under transistors and connected to source/drain regions of the transistors.

US Patent Application Publication No. 2022/0344255 discloses a structure of a standard cell using the CFET technique and interconnects right under transistors.

An analog circuit handling an analog signal is one of basic circuits constituting a semiconductor integrated circuit. Since the analog signal handled by the analog circuit is a continuously-changing signal, full attention must be paid, at its layout design, for preventing variations in signal. In particular, for a circuit handling differential signals, such as a differential amplifier, it is required to prevent variations between circuits that operate differentially.

In the cited patent document, however, no examination has been made on the layout structure using CFETs for an analog circuit.

An objective of the present disclosure is presenting a layout structure using CFETs for an analog circuit including transistors that perform differential amplification.

### SUMMARY

According to the first mode of the disclosure, a semiconductor integrated circuit device includes: a first transistor of a first conductivity type having a first active region forming a channel, source, and drain of a transistor; a second transistor of the first conductivity type located at a same position as the first transistor in a depth direction and having a second active region forming a channel, source, and drain of a transistor; a first dummy transistor of a second conductivity type located at a different position from the first transistor in the depth direction, placed at a position overlapping the first transistor in planar view, and having a third active region forming a channel, source, and drain of a transistor; and a second dummy transistor of the second conductivity type located at a same position as the first dummy transistor in the depth direction, placed at a position overlapping the second transistor in planar view, and having a fourth active region forming a channel, source, and drain of a transistor, wherein one of differential input terminals is connected to gates of the first transistor and the first dummy transistor, and the other of the differential input terminals is connected to gates of the second transistor and the second dummy transistor, the first active region and the second active region are formed line-symmetrically with respect to a predetermined straight line as an axis in planar view, the third active region and the fourth active region are formed line-symmetrically with respect to the predetermined straight line in planar view, and in the third and fourth active regions, the sources and the drains located line-symmetrically with respect to the predetermined straight line have a same electrical connection state.

According to the above mode, the semiconductor integrated circuit device includes first and second transistors that perform differential amplification. First and second dummy transistors are formed at positions different from the first and second transistors in the depth direction and overlapping the first and second transistors in planar view. The first and second active regions of the first and second transistors are formed line-symmetrically with respect to a predetermined straight line in planar view. The third and fourth active regions of the first and second dummy transistors are also formed line-symmetrically with respect to the same predetermined straight line. In the third and fourth active regions, the sources and the drains at the symmetric positions have the same electrical connection state. Therefore, since variations in the characteristics of the first and second transistors that perform differential operation are prevented, it is possible to prevent variations between differential output signals.

According to the present disclosure, a layout structure using CFETs capable of preventing variations in differential operation can be implemented.

### BRIEF DESCRIPTION OF THE DRAWINGS

FIG. 1 shows a circuit configuration example of a differential amplifier according to the first embodiment.

FIG. 2 is a plan view showing a layout structure example of the differential amplifier shown in FIG. 1, illustrating the structure of an upper part.

FIG. 3 is a plan view showing the layout structure example of the differential amplifier shown in FIG. 1, illustrating the structure of a lower part.

FIG. 4 is a cross-sectional view of the layout structure shown in FIGS. 2 and 3.

FIG. 5 shows an alteration of the layout structure of FIG. 3.

FIG. 6 shows a circuit configuration example of a differential amplifier according to the second embodiment.

FIG. 7 is a plan view showing a layout structure example of the differential amplifier shown in FIG. 6, illustrating the structure of an upper part.

FIG. 8 is a plan view showing the layout structure example of the differential amplifier shown in FIG. 6, illustrating the structure of a lower part.

### DETAILED DESCRIPTION

Embodiments of the present disclosure will be described hereinafter with reference to the accompanying drawings. In the following embodiments, the semiconductor integrated circuit device includes nanosheet field effect transistors (FETs). According to the present disclosure, however, transistors included in the semiconductor integrated circuit device are not limited to nanosheet FETs.

As used herein, “VDD” and “VSS” refer to the power supply voltages or the power supplies themselves. Also, “INP”, “INN”, “OUTP”, and “OUTN” refer to the signals or the signal terminals. As used herein, an expression indicating that sizes such as widths are identical, like the “same wiring width,” is to be understood as including a range of manufacturing variations.

### First Embodiment

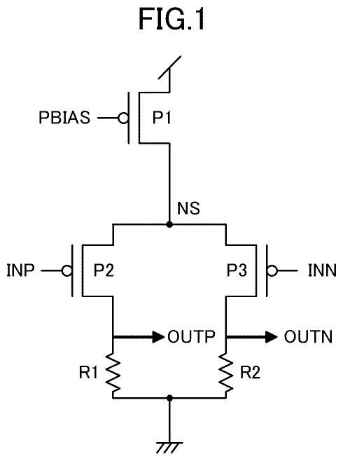

FIG. 1 is a circuit diagram showing a circuit configuration example of a differential amplifier according to the first embodiment. The differential amplifier is one type of the analog circuit. The differential amplifier of FIG. 1 includes p-type transistors P1, P2, and P3 and resistances R1 and R2. The transistors P2 and P3 have the same size, and the resistances R1 and R2 have the same resistance value.

The transistor P1 functions as a current source. The transistor P1 is connected between the power supply VDD and a node NS and supplied with a bias voltage PBIAS at its gate. The transistor P1 supplies a current to the node NS.

The transistors P2 and P3 are both connected to the node NS at their sources. The transistor P2 is connected to a differential input terminal INP at its gate, and connected to one end of the resistance R1 at its drain. The transistor P3 is connected to a differential input terminal INN at its gate, and connected to one end of the resistance R2 at its drain. The other ends of the resistances R1 and R2 are connected to the power supply VSS. The drain of the transistor P2 is connected to a differential output terminal OUTP, and the drain of the transistor P3 is connected to a differential output terminal OUTN.

The differential amplifier of FIG. 1 amplifies differential input signals input into the differential input terminals INP and INN with a predetermined differential gain and outputs the amplified signals from the differential output terminals OUTP and OUTN.

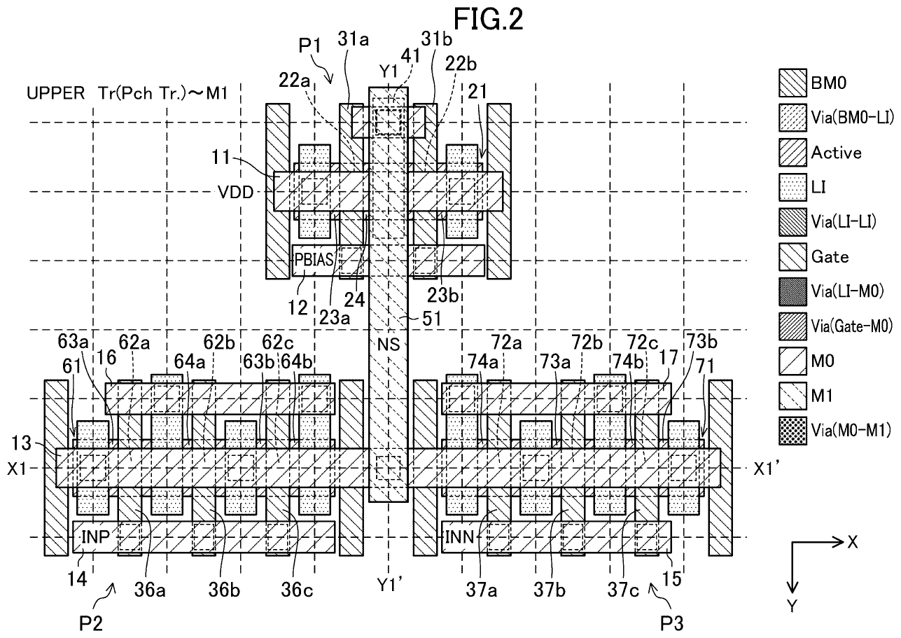

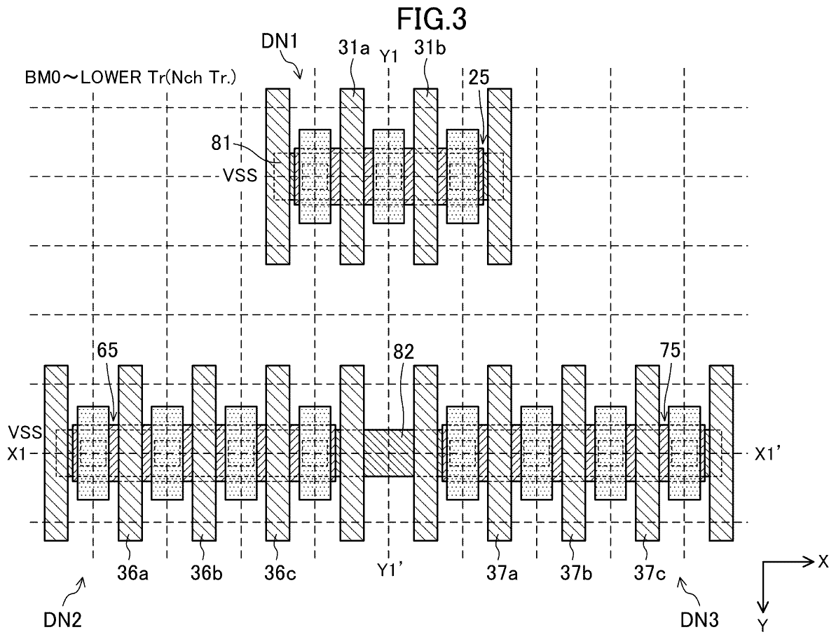

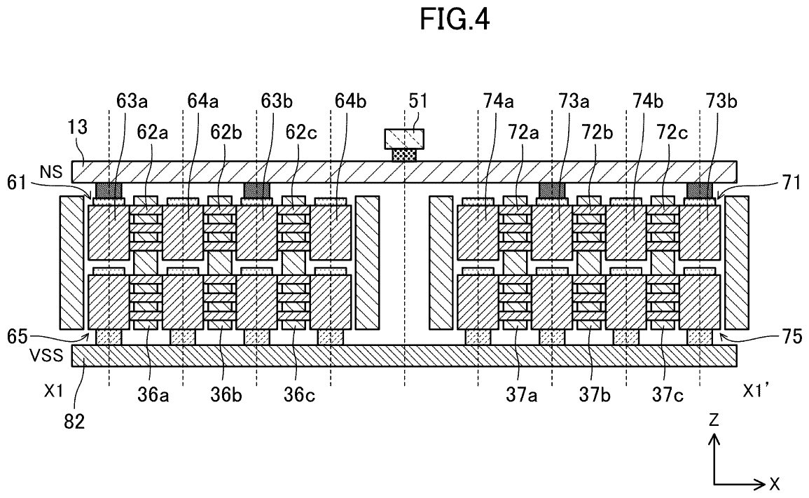

FIGS. 2 to 4 are views showing a layout structure example, using CFETs, of the differential amplifier of FIG. 1. Specifically, FIG. 2 is a plan view of an upper part that is a part including upper transistors formed in the portion farther from the substrate, FIG. 3 is a plan view of a lower part that is a part including lower transistors formed in the portion closer to the substrate, and FIG. 4 is a cross-sectional view taken along line X1-X1′ in FIGS. 2 and 3. In this layout structure example, p-type nanosheet FETs are formed in the upper part, and n-type nanosheet FETs are formed in the lower part. The transistors P1, P2, and P3 in the circuit diagram of FIG. 1 are formed in the upper part. In the lower part, dummy transistors DN1, DN2, and DN3 that are not illustrated in the circuit diagram of FIG. 1 are formed.

Note that, in the plan views such as FIG. 2, the horizontal direction in the figure is hereinafter referred to as an X direction, the vertical direction in the figure as a Y direction, and the direction normal to the substrate plane as a Z direction (corresponding to the depth direction). Also, hereinafter, the same components are denoted by the same reference characters, and description of such components may be omitted.

The transistor P1 is formed in the center in the upper half of FIG. 2. In FIG. 2, the transistor P1 is constituted by two parallel-connected transistors.

In an M0 layer, interconnects 11 and 12 extending in the X direction are formed. The M0 layer is an interconnect layer in the upper-side portion of a semiconductor chip. The interconnect 11 is a power line supplying VDD, and the interconnect 12 supplies the bias voltage PBIAS.

Below the power line 11, formed is an active region 21 forming the channels, sources, and drains of p-type nanosheet FETs that are to be the transistor P1. The active region 21 includes nanosheets 22a and 22b that are to be the channels of the p-type nanosheet FETs. Portions 23a and 23b that are to be the sources of the p-type nanosheet FETs in the active region 21 are connected to the power line 11 through local interconnects and vias.

Note that, in the active region, portions that are to be the source and the drain on both sides of a nanosheet are formed by epitaxial growth from the nanosheet, for example.

Gate interconnects 31a and 31b extend in the Y direction and also extend in the Z direction from the upper part over to the lower part. The gate interconnects 31a and 31b surround the peripheries of the nanosheets 22a and 22b, respectively, in the Y direction and the Z direction through gate insulating films (not shown). The gate interconnects 31a and 31b are to be the gates of the p-type nanosheet FETs, and connected to the interconnect 12 in the M0 layer through vias.

A local interconnect 41 extending in the Y direction is connected to a portion 24 that is to be the drains of the p-type nanosheet FETs in the active region 21. The local interconnect 41 is connected to an interconnect 51 formed in an M1 layer through a via, an M0 interconnect, and a via. The M1 layer is an interconnect layer located above the M0 layer. The interconnect 51 is an interconnect corresponding to the node NS, and extends in the Y direction to the region in which the transistors P2 and P3 in the lower half of the figure are formed.

The transistors P2 and P3 are formed in the lower half of FIG. 2. In FIG. 2, the transistors P2 and P3 are each constituted by three parallel-connected transistors. The transistors P2 and P3 are placed on the left and right sides, respectively, of the interconnect 51 in the figure. The planar layouts of the transistors P2 and P3 are line-symmetric with respect to line Y1-Y1′ extending in the Y direction. The M1 interconnect 51 is placed on the center line Y1-Y1′ of the line symmetry.

In the M0 layer, an interconnect 13 extending in the X direction is formed from the transistor P2 over to the transistor P3. The M0 interconnect 13 is connected to the M1 interconnect 51 through a via. Also, in the M0 interconnect, interconnects 14, 15, 16, and 17 extending in the X direction are formed. The interconnect 14 corresponds to the differential input terminal INP, and the interconnect 15 corresponds to the differential input terminal INN. The interconnect 16 is connected to the resistance R1 not shown, and the interconnect 17 is connected to the resistance R2 not shown.

Below the M0 interconnect 13, formed are an active region 61 forming the channels, sources, and drains of p-type nanosheet FETs that are to be the transistor P2 and an active region 71 forming the channels, sources, and drains of p-type nanosheet FETs that are to be the transistor P3.

The active region 61 includes nanosheets 62a, 62b, and 62c that are to be the channels of the p-type nanosheet FETs. Portions 63a and 63b that are to be the sources of the p-type nanosheet FETs in the active region 61 are connected to the M0 interconnect 13 through local interconnects and vias. Also, portions 64a and 64b that are to be the drains of the p-type nanosheet FETs in the active region 61 are connected to the M0 interconnect 16 through local interconnects and vias.

Gate interconnects 36a, 36b, and 36c extend in the Y direction and also extend in the Z direction from the upper part over to the lower part. The gate interconnects 36a, 36b, and 36c surround the peripheries of the nanosheets 62a, 62b, and 62c, respectively, in the Y direction and the Z direction through gate insulating films (not shown). The gate interconnects 36a, 36b, and 36c are to be the gate of the transistor P2, and are connected to the interconnect 14 in the M0 layer through vias.

The active region 71 includes nanosheets 72a, 72b, and 72c that are to be the channels of the p-type nanosheet FETs. Portions 73a and 73b that are to be the sources of the p-type nanosheet FETs in the active region 71 are connected to the M0 interconnect 13 through local interconnects and vias. Also, portions 74a and 74b that are to be the drains of the p-type nanosheet FETs in the active region 71 are connected to the M0 interconnect 17 through local interconnects and vias.

Gate interconnects 37a, 37b, and 37c extend in the Y direction and also extend in the Z direction from the upper part over to the lower part. The gate interconnects 37a, 37b, and 37c surround the peripheries of the nanosheets 72a, 72b, and 72c, respectively, in the Y direction and the Z direction through gate insulating films (not shown). The gate interconnects 37a, 37b, and 37c are to be the gate of the transistor P3, and are connected to the interconnect 15 in the M0 layer through vias.

In FIG. 3, an active region 25 is formed at a position overlapping the active region 21 of the transistor P1 in planar view. Also, active regions 65 and 75 are formed at positions overlapping the active regions 61 and 71 of the transistors P2 and P3, respectively, in planar view. The active regions 25, 65, and 75 form the channels, sources, and drains of n-type nanosheet FETs that are to be the dummy transistors DN1, DN2, and DN3, respectively.

In a BM0 layer, interconnects 81 and 82 extending in the X direction are formed. The BM0 layer is an interconnect layer in the backside portion of the semiconductor chip. The interconnects 81 and 82 are power lines supplying VSS.

The gate interconnects 31a and 31b surround the peripheries of nanosheets in the active region 25 in the Y direction and the Z direction through gate insulating films (not shown). The gate interconnects 36a, 36b, and 36c surround the peripheries of nanosheets in the active region 65 in the Y direction and the Z direction through gate insulating films (not shown). The gate interconnects 37a, 37b, and 37c surround the peripheries of nanosheets in the active region 75 in the Y direction and the Z direction through gate insulating films (not shown).

Portions that are to be sources and drains in the active region 25 are connected to the BM0 interconnect 81 through vias. Portions that are to be sources and drains in the active regions 65 and 75 are connected to the BM0 interconnect 82 through vias.

The layout structure shown in FIGS. 2 to 4 has the following features.

The layouts of the transistors P2 and P3 into which differential signals are input are formed line-symmetrically with respect to the line Y1-Y1′ as the symmetric axis.

Specifically, both the transistors P2 and P3 are constituted by three transistors connected in parallel. Therefore, the transistors P2 and P3 have the same transistor size. Also, in the transistors P2 and P3, the gates, the sources, and the drains constituting the transistors are placed symmetrically. The vias connected to the gates, the sources, and the drains are also placed symmetrically. The interconnects (local interconnects and M0 interconnects) connected to the transistors and the vias between the interconnects are also placed symmetrically. The interconnect 51 corresponding to the node NS is placed on the line Y1-Y1′ as the symmetric axis, and connected to the transistors P2 and P3.

Having the symmetric arrangement as described above, since variations in characteristics between the transistors P2 and P3 are prevented, it is possible to prevent variations between the differential output signals.

Also, the n-type dummy transistors DN2 and DN3 formed under the transistors P2 and P3 are formed line-symmetrically with respect to the line Y1-Y1′ as the symmetric axis.

Specifically, the two dummy transistors DN2 and DN3 are each constituted by three transistors each lying under the corresponding one of the three transistors constituting the transistor P2 or P3. The gates are formed integrally with the gates of the transistors P2 and P3 in the upper part, and therefore supplied with the same differential input signals INP and INN supplied to the transistors P2 and P3. The sources and the drains are all connected to the BM0 interconnect 82 supplying VSS through vias. The interconnects and the vias connected to the dummy transistors DN2 and DN3 are placed line-symmetrically with respect to the line Y1-Y1′ as the symmetric axis.

As described above, by forming the dummy transistors DN2 and DN3 in the lower part, above which the transistors P2 and P3 are formed, symmetrically in their circuits and layouts, variations in the finished sizes of the transistors including the transistors P2 and P3 in the upper part are prevented.

Moreover, since the gates of the transistors P2 and P3 and the underlying dummy transistors DN2 and DN3 are integrally formed, not only the gates of the transistors P2 and P3 but also the gates of the dummy transistors DN2 and DN3 work as loads against the differential input signals INP and INN. In the above configuration, however, since the dummy transistors DN2 and DN3 are also formed symmetrically in their circuits and layouts, it is possible to prevent variations in loads related to the differential input signals INP and INN.

As described above, according to this embodiment, variations in differential operation in the differential amplifier can be prevented. That is, the semiconductor integrated circuit device according to this embodiment includes the transistors P2 and P3 that perform differential amplification. The dummy transistors DN2 and DN3 are formed at positions different from the transistors P2 and P3 in the depth direction and overlapping the transistors P2 and P3 in planar view. The active regions 61 and 71 of the transistors P2 and P3 are formed line-symmetrically with respect to the line Y1-Y1′ in planar view. The active regions 65 and 75 of the dummy transistors DN2 and DN3 are also formed line-symmetrically with respect to the line Y1-Y1′. In the active regions 65 and 75, the sources and the drains are all connected to the power supply VSS. With this configuration, since variations in the characteristics of the transistors P2 and P3 that perform differential operation are prevented, it is possible to prevent variations between the differential output signals.

### (Alteration)

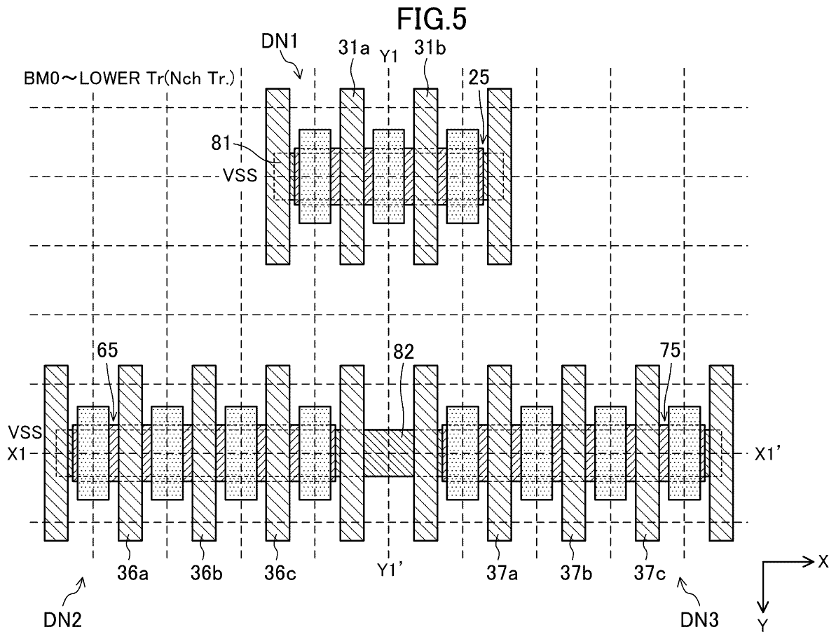

FIG. 5 is a view showing a layout structure according to an alteration, which is a plan view of the lower part including lower transistors. The layout structure of FIG. 5 is roughly the same as that of FIG. 3, except that the active region 25 is not connected to the BM0 interconnect 81 and the active regions 65 and 75 are not connected to the BM0 interconnect 82. That is, all of the sources and drains of the dummy transistors DN2 and DN3 are floating.

In this alteration, also, the dummy transistors DN2 and DN3 in the lower part, above which the transistors P2 and P3 are formed, are formed symmetrically in their circuits and layouts. Therefore, similar effects to those in the above embodiment can be obtained.

### Second Embodiment

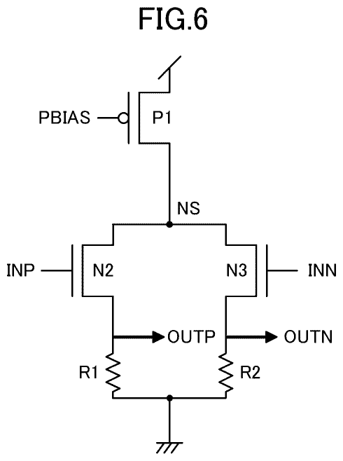

FIG. 6 is a circuit diagram showing a circuit configuration example of a differential amplifier according to the second embodiment. The differential amplifier of FIG. 6 includes a p-type transistor P1, n-type transistors N2 and N3, and resistances R1 and R2. The transistors N2 and N3 have the same size, and the resistances R1 and R2 have the same resistance value.

The differential amplifier of FIG. 6 is different from the differential amplifier of FIG. 1 in that the p-type transistors P2 and P3 that perform differential operation are replaced with the n-type transistors N2 and N3. The other configuration and operation are similar to those of the differential amplifier of FIG. 1, and therefore detailed description thereof is omitted here.

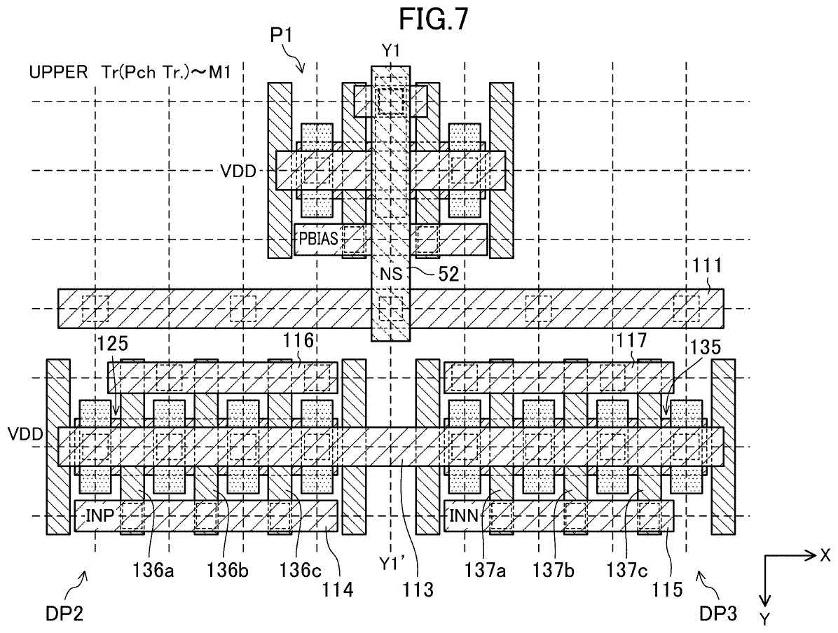

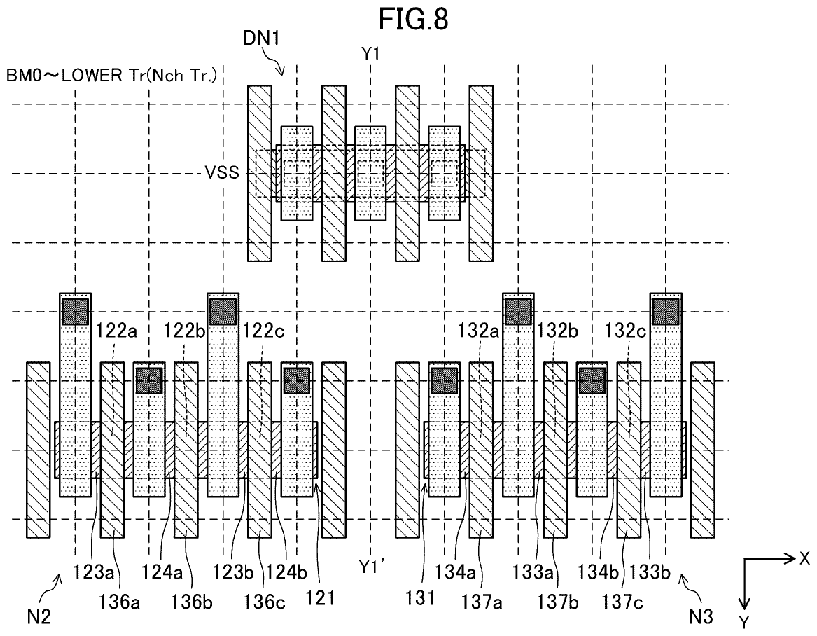

FIGS. 7 and 8 are views showing a layout structure example, using CFETs, of the differential amplifier of FIG. 6, where FIG. 7 is a plan view of an upper part and FIG. 8 is a plan view of a lower part. In this layout structure example, p-type nanosheet FETs are formed in the upper part, and n-type nanosheet FETs are formed in the lower part. Note that, since the cross-sectional structure of this differential amplifier is easily known by analogy from the description in the first embodiment, illustration thereof is omitted here.

The transistor P1 in the circuit diagram of FIG. 6 is formed in the upper part, and the transistors N2 and N3 in the circuit diagram of FIG. 6 are formed in the lower part. Also, in the lower part, a dummy transistor DN1 not shown in the circuit diagram of FIG. 6 is formed at a position overlapping the transistor P1 in planar view. In the upper part, dummy transistors DP2 and DP3 not shown in the circuit diagram of FIG. 6 are formed at positions overlapping the transistors N2 and N3 in planar view.

The transistor P1 is formed in the center in the upper half of FIG. 7. Also, in FIG. 8, n-type nanosheet FETs that are to be the dummy transistor DN1 are formed at a position overlapping the transistor P1. This configuration of the transistor P1 and the dummy transistor DN1 is similar to that shown in FIGS. 2 and 3, and therefore description thereof is omitted here. An M1 interconnect 52 corresponding to the node NS is connected to an M0 interconnect 111 extending in the X direction through a via.

In the lower half of FIG. 7, in the M0 layer, an interconnect 113 extending in the X direction is formed. The interconnect 113 is a power line supplying VDD. Also, in the M0 layer, interconnects 114, 115, 116, and 117 extending in the X direction are formed. The interconnect 114 corresponds to the differential input terminal INP, and the interconnect 115 corresponds to the differential input terminal INN. The interconnect 116 is connected to the resistance R1 not shown, and the interconnect 117 is connected to the resistance R2 not shown.

The transistors N2 and N3 are formed in the lower half of FIG. 8. In FIG. 8, the transistors N2 and N3 are each constituted by three parallel-connected transistors. The planar layouts of the transistors N2 and N3 are line-symmetric with respect to the line Y1-Y1′ extending in the Y direction.

An active region 121 forming the channels, sources, and drains of n-type nanosheet FETs that are to be the transistor N2 is formed. Also, an active region 131 forming the channels, sources, and drains of n-type nanosheet FETs that are to be the transistor N3 is formed.

The active region 121 includes nanosheets 122a, 122b, and 122c that are to be the channels of the n-type nanosheet FETs. Portions 123a and 123b that are to be the sources of the n-type nanosheet FETs in the active region 121 are connected to the M0 interconnect 111 through local interconnects and vias. Also, portions 124a and 124b that are to be the drains of the n-type nanosheet FETs in the active region 121 are connected to the M0 interconnect 116 through local interconnects and vias.

Gate interconnects 136a, 136b, and 136c extend in the Y direction and also extend in the Z direction from the upper part over to the lower part. The gate interconnects 136a, 136b, and 136c surround the peripheries of the nanosheets 122a, 122b, and 122c, respectively, in the Y direction and the Z direction through gate insulating films (not shown). The gate interconnects 136a, 136b, and 136c are to be the gate of the transistor N2, and connected to the interconnect 114 in the M0 layer through vias.

The active region 131 includes nanosheets 132a, 132b, and 132c that are to be the channels of the n-type nanosheet FETs. Portions 133a and 133b that are to be the sources of the n-type nanosheet FETs in the active region 131 are connected to the M0 interconnect 111 through local interconnects and vias. Also, portions 134a and 134b that are to be the drains of the n-type nanosheet FETs in the active region 131 are connected to the M0 interconnect 117 through local interconnects and vias.

Gate interconnects 137a, 137b, and 137c extend in the Y direction and also extend in the Z direction from the upper part over to the lower part. The gate interconnects 137a, 137b, and 137c surround the peripheries of the nanosheets 132a, 132b, and 132c, respectively, in the Y direction and the Z direction through gate insulating films (not shown). The gate interconnects 137a, 137b, and 137c are to be the gate of the transistor N3, and connected to the interconnect 115 in the M0 layer through vias.

In FIG. 7, active regions 125 and 135 are formed at positions overlapping the active regions 121 and 131 of the transistors N2 and N3, respectively, in planar view. The active regions 125 and 135 form the channels, sources, and drains of p-type nanosheet FETs that are to be the dummy transistors DP2 and DP3, respectively.

Portions that are to be the sources and the drains in the active regions 125 and 135 are connected to the M0 interconnect 113 through local interconnects and vias.

The layout structure shown in FIGS. 7 and 8 has similar features to those in the first embodiment. That is, the layouts of the transistors N2 and N3 into which differential signals are input are formed line-symmetrically with respect to the line Y1-Y1′ as the symmetric axis. Specifically, both the transistors N2 and N3 are constituted by three transistors connected in parallel. Therefore, the transistors N2 and N3 have the same transistor size. Also, in the transistors N2 and N3, the gates, the sources, and the drains constituting the transistors are placed symmetrically. The interconnects and the vias connected to the transistors are also placed symmetrically.

Having the symmetric arrangement as described above, since variations in characteristics between the transistors N2 and N3 are prevented, it is possible to prevent variations between the differential output signals.

Also, the p-type dummy transistors DP2 and DP3 formed above the transistors N2 and N3 are formed line-symmetrically with respect to the line Y1-Y1′ as the symmetric axis.

Specifically, each of the two dummy transistors DP2 and DP3 is constituted by three transistors each lying above the corresponding one of the three transistors constituting the transistor N2 or N3. The gates are formed integrally with the gates of the transistors N2 and N3 in the lower part, and therefore supplied with the same differential input signals INP and INN supplied to the transistors N2 and N3. The sources and the drains are all connected to the M0 interconnect 113 supplying VDD through vias. The interconnects and the vias connected to the dummy transistors DP2 and DP3 are placed line-symmetrically with respect to the line Y1-Y1′ as the symmetric axis.

As described above, by forming the dummy transistors DP2 and DP3 in the upper part, below which the transistors N2 and N3 are formed, symmetrically in their circuits and layouts, it is possible to prevent variations in the finished sizes of the transistors including the transistors N2 and N3 in the lower part.

Moreover, since the gates of the transistors N2 and N3 and the overlying dummy transistors DP2 and DP3 are integrally formed, not only the gates of the transistors N2 and N3 but also the gates of the dummy transistors DP2 and DP3 work as loads against the differential input signals INP and INN. In the above configuration, however, since the dummy transistors DP2 and DP3 are also formed symmetrically in their circuits and layouts, variations in loads related to the differential input signals INP and INN can be prevented.

As described above, according to this embodiment, variations in differential operation in the differential amplifier can be prevented. That is, the semiconductor integrated circuit device according to this embodiment includes the transistors N2 and N3 that perform differential amplification. The dummy transistors DP2 and DP3 are formed at positions different from the transistors N2 and N3 in the depth direction and overlapping the transistors N2 and N3 in planar view. The active regions 121 and 131 of the transistors N2 and N3 are formed line-symmetrically with respect to the line Y1-Y1′ in planar view. The active regions 125 and 135 of the dummy transistors DP2 and DP3 are also formed line-symmetrically with respect to the line Y1-Y1′. In the active regions 125 and 135, the sources and the drains are all connected to the power supply VDD. With this configuration, since variations in the characteristics of the transistors N2 and N3 that perform differential operation are prevented, it is possible to prevent variations between the differential output signals.

Note that, as in the alteration of the first embodiment, the active regions 125 and 135 constituting the dummy transistors DP2 and DP3 may be configured not to be connected to the M0 interconnect 113. That is, all of the sources and drains of the dummy transistors DP2 and DP3 may be floating.

### Other Embodiments

### (No. 1)

In the embodiments described above, the p-type nanosheet FETs are formed in the upper part and the n-type nanosheet FETs are formed in the lower part. However, the conductivity types may be reversed, to form n-type nanosheet FETs in the upper part and p-type nanosheet FETS in the lower part.

### (No. 2)

In the embodiments described above, all of the sources and drains of the dummy transistors overlapping the transistors that perform differential operation in planar view are connected to power supply, or are floating. However, the configuration is not limited to this. For example, all of the sources and drains of the dummy transistors may be connected to a predetermined node other than power supply.

Also, all of the sources and drains of the dummy transistors do not necessarily need to have the same electrical connection state. That is, according to the present disclosure, in the dummy transistors overlapping the transistors that perform differential operation, it is only necessary for sources and drains located at line-symmetric positions to have the same electrical connection state. The electrical connection state as used herein may be any of the state connected to power supply, the floating state, and the state connected to a predetermined node other than power supply.

### (No. 3)

While the transistors that perform differential operation are each constituted by three parallel-connected transistors in the embodiments described above, the configuration is not limited to this. That is, the transistors that perform differential operation may be each constituted by less than three transistors or constituted by more than three transistors.

Also, while the transistors constituting the transistors that perform differential operation are arranged in the X direction in the embodiments described above, the configuration is not limited to this. For example, they may be arranged in the Y direction, or may be arranged in an array in the X and Y directions.

### (No. 4)

While the differential amplifiers shown in FIGS. 1 and 6 are taken as examples to describe the layout structures in the above embodiments, the circuit configuration to which the present disclosure is applicable is not limited to this. That is, for circuits including transistors that perform differential operation, such as differential amplifiers different in configuration from those in FIGS. 1 and 6, similar effects can be obtained by applying the layout structures as described above to the transistors that perform differential operation.

### (No. 5)

In the embodiments described above, the transistors that perform differential operation and the dummy transistors overlapping these transistors in planar view have layout structures in which the active regions, the interconnects, and the vias are all line-symmetric. Note however that the effects described in the embodiments can be obtained if only the active regions are line-symmetric even though the interconnects and the vias are not line-symmetric. Also, more effects will be obtained if the local interconnects connected to the active regions are line-symmetric, or more effects will be obtained if the gates of the transistors are line-symmetric. Moreover, variations in differential operation can be prevented more effectively if the interconnects and the vias connected to the transistors are line-symmetric.

In the embodiments descried above, the nanosheet is illustrated to have a structure of three sheets lying one above another and having a rectangular cross-sectional shape. However, the number of sheets and cross-sectional shape of the sheet structure of the nanosheet are not limited to these.

While the transistors are nanosheet FETs in the embodiments described above, the configuration is not limited to this. For example, fin FETs or other types of transistors may be used.

According to the present disclosure, variations in differential operation can be prevented. The present disclosure is therefore useful for improvement in the performance of a semiconductor integrated circuit device.

1. A semiconductor integrated circuit device, comprising:
a first transistor of a first conductivity type having a first active region forming a channel, source, and drain of a transistor;
a second transistor of the first conductivity type located at a same position as the first transistor in a depth direction and having a second active region forming a channel, source, and drain of a transistor;
a first dummy transistor of a second conductivity type located at a different position from the first transistor in the depth direction, placed at a position overlapping the first transistor in planar view, and having a third active region forming a channel, source, and drain of a transistor; and
a second dummy transistor of the second conductivity type located at a same position as the first dummy transistor in the depth direction, placed at a position overlapping the second transistor in planar view, and having a fourth active region forming a channel, source, and drain of a transistor,
wherein
one of differential input terminals is connected to gates of the first transistor and the first dummy transistor, and the other of the differential input terminals is connected to gates of the second transistor and the second dummy transistor,
the first active region and the second active region are formed line-symmetrically with respect to a predetermined straight line as an axis in planar view,
the third active region and the fourth active region are formed line-symmetrically with respect to the predetermined straight line in planar view, and
in the third and fourth active regions, the sources and the drains located line-symmetrically with respect to the predetermined straight line have a same electrical connection state.

2. The semiconductor integrated circuit device of claim 1, wherein
the electrical connection state is any of being connected to power supply, being floating, and being connected to a predetermined node other than power supply.

3. The semiconductor integrated circuit device of claim 1, wherein
a local interconnect connected to the first active region and a local interconnect connected to the second active region are formed line-symmetrically with respect to the predetermined straight line in planar view, and
a local interconnect connected to the third active region and a local interconnect connected to the fourth active region are formed line-symmetrically with respect to the predetermined straight line in planar view.

4. The semiconductor integrated circuit device of claim 1, wherein
the gate of the first transistor and the gate of the second transistor are formed line-symmetrically with respect to the predetermined straight line in planar view, and
the gate of the first dummy transistor and the gate of the second dummy transistor are formed line-symmetrically with respect to the predetermined straight line in planar view.
